(19) United States
(12) Patent Application Publication
(10) Pub. No.: US 2010/0096746 A1
(43) Pub. Date: Apr. 22, 2010

(54) PACKAGE MODULE STRUCTURE OF COMPOUND SEMICONDUCTOR DEVICES AND FABRICATING METHOD THEREOF

(75) Inventors: WEN LIANG TSENG, Hsinchu County (TW); LUNG HSIN CHEN, Hsinchu County (TW); CHESTER KUO, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/580,497

(22) Filed: Oct. 16, 2009

(30) Foreign Application Priority Data
Oct. 21, 2008 (TW) 097140263

(51) Int. Cl. H01L 23/36; H01L 21/58

(52) U.S. Cl. 257/706; 438/126; 257/723; 257/E23.101; 257/E21.505

(57) ABSTRACT

A compound semiconductor device package module structure includes a heat dissipation film, a dielectric layer, a plurality of compound semiconductor dies, means for mounting the compound semiconductor dies on the heat dissipation film, and a transparent encapsulation material. The dielectric layer includes a plurality of openings formed on the heat dissipation film. The compound semiconductor dies are placed on the heat dissipation film in the openings, and adjacent two compound semiconductor dies are separated by the dielectric layer. The transparent encapsulation material covers the compound semiconductor dies.

### BACKGROUND OF THE INVENTION

(A) Field of the Invention

The present invention relates to a package module structure of compound semiconductor devices and fabricating method thereof, and more particularly, to a thin package module structure for a photoelectric semiconductor device and fabricating method thereof.

(B) Description of the Related Art

Because the light emitting diode (LED) pertaining to the photoelectric device has advantages of a small body, high efficiency and long lifetime, it is deemed as an excellent illuminant source for the next generation. Furthermore, LCD (liquid crystal display) technology is developing rapidly and full color is the current trend in electronic product displays. Therefore, the white series LEDs are not only applicable to indication lights and large size display screens but also to most consumer electronics products such as mobile phones and personal digital assistants (PDA).

FIG. 1 is a schematic cross-sectional diagram of the conventional SMD (surface mount device) of an LED device. An LED die 12 is mounted on an N-type conductive copper foil 13b covering an insulation layer 13c through die bonding paste 11, and is electrically connected to a P-type conductive copper foil 13a and the N-type conductive copper foil 13b through metal wires 15. The assembly of the P-type conductive copper foil 13a, N-type conductive copper foil 13b and insulation layer 13c form a substrate 13 with circuit pattern. Furthermore, a transparent encapsulation material 14 covers the substrate 13, metal wires 15 and die 12 so that the whole LED device 10 can be protected against damage from environmental and external forces.

The LED device 10 utilizes a common printed circuit board (PCB) as the substrate 13. The total thickness of the LED device 10 is limited by the insulation layer 13c of the substrate 13; hence it cannot be reduced further. However, the current trend of consumer electronics products is towards a light, thin, short and small body. Accordingly, each of the internal devices of the consumer electronics product and its shell needs to be miniaturized. In addition, the insulation layer 13c is made mostly of epoxy resin with poor heat dissipation, and therefore is not suitable for a high power chemical compound semiconductor device as a heat-transferring path. If plural LED devices 10 constitute an LED module, a more serious heat dissipation problem may occur.

In view of the above, the consumer electronics market is in urgent need of a thin type package module structure of compound semiconductor device. The device not only needs to have a reduced thickness for saving space, but also needs to address the heat dissipation problem. With such a device, reliable, high power electronics products can be more easily manufactured.

### SUMMARY OF THE INVENTION

One aspect of the present invention provides a package module structure of compound semiconductor devices and a fabricating method thereof. The package module structure of compound semiconductor devices has a heat dissipation film for effectively dissipating heat, so as to resolve the poor heat dissipation problem. Moreover, by using a thin substrate, the package module structure of compound semiconductor devices can be made thinner for saving space.

In accordance with the present invention, a package module structure of compound semiconductor devices includes a heat dissipation film, a dielectric layer, a plurality of compound semiconductor dies, means for mounting the compound semiconductor dies on the heat dissipation film, and a transparent encapsulation material. The dielectric layer includes a plurality of openings and is formed on the heat dissipating film. The plurality of compound semiconductor dies are formed on the heat dissipation film in the openings of the dielectric layer, and adjacent pairs of compound semiconductor dies are separated by the dielectric layer. The transparent encapsulation material overlays the compound semiconductor dies.

In an embodiment, a package module structure of compound semiconductor devices further includes a circuit board (e.g., a flexible printed circuit). The circuit board includes a first electrode and a second electrode disposed on the dielectric layer at two sides of the compound semiconductor die. Means for mounting the compound semiconductor dies on the heat dissipation film include die bonding paste connecting the compound semiconductor dies and the heat dissipation film and wires connecting the compound semiconductor dies to the first electrode and the second electrode. In an embodiment, the thickness of the package module structure of compound semiconductor devices may be between 0.4 and 0.8 mm.

In accordance with another embodiment of the present invention, the heat dissipation film is an electrically conductive film with a circuit pattern. The electrically conductive film has a first electrode and a second electrode disposed at two sides of the compound semiconductor die. Means for mounting the compound semiconductor dies on the heat dissipation film include flip chip bonding connecting the compound semiconductor die to the first electrode and the second electrode of the electrically conductive film. A plurality of bumps may electrically connect the compound semiconductor dies to the first electrode and the second electrode of the electrically conductive film. In this embodiment, the thickness of the package module structure may be between 0.15 and 0.3 mm

In accordance with a first embodiment, a method for fabricating a package module structure of compound semiconductor devices includes the steps of: providing a heat dissipation film; forming a dielectric layer on the heat dissipation film, the dielectric layer comprising a plurality of openings; mounting a plurality of compound semiconductor dies on the heat dissipation film in the openings; forming a circuit board on the dielectric layer, the circuit board comprising a first electrode and a second electrode disposed on the dielectric layer at two sides of the compound semiconductor die; electrically connecting the plurality of compound semiconductor dies to the first electrode and the second electrode; and overlaying a transparent encapsulation material on the compound semiconductor dies. In an embodiment, the plurality of compound semiconductor dies, the first electrode and the second electrode are electrically connected by wire bonding using metal wires.

In accordance with a second embodiment, a method for fabricating a package module structure of compound semiconductor devices includes the steps of: providing a heat dissipation film having a first electrode and a second electrode; forming a dielectric layer on the heat dissipation film, the dielectric layer comprising a plurality of openings; mounting a plurality of compound semiconductor dies on the heat dissipation film in the openings and electrically connecting the compound semiconductor dies to the first electrode and the second electrode; and overlaying a transparent encapsulation material on the compound semiconductor dies. In an embodiment, the step of mounting a plurality of compound semiconductor dies on the heat dissipation film in the openings is performed by flip chip bonding and electrically connecting the compound semiconductor dies to the first electrode and the second electrode through a plurality of bumps.

In practice, the package module structure of compound semiconductor devices may be formed on a temporary substrate, and then the temporary substrate is removed after the compound semiconductor dies are covered with the transparent encapsulation material.

### BRIEF DESCRIPTION OF THE DRAWINGS

The objectives and advantages of the present invention will become apparent upon reading the following description and upon reference to the accompanying drawings in which:

FIG. 1 is a schematic cross sectional diagram of the conventional SMD (surface mount device) of an LED device;

FIGS. 2A through 2H show the manufacturing steps of the package module structure of compound semiconductor devices in accordance with a first embodiment of the present invention; and

FIGS. 3A through 3E show the manufacturing steps of the package module structure of compound semiconductor devices in accordance with a second embodiment of the present invention.

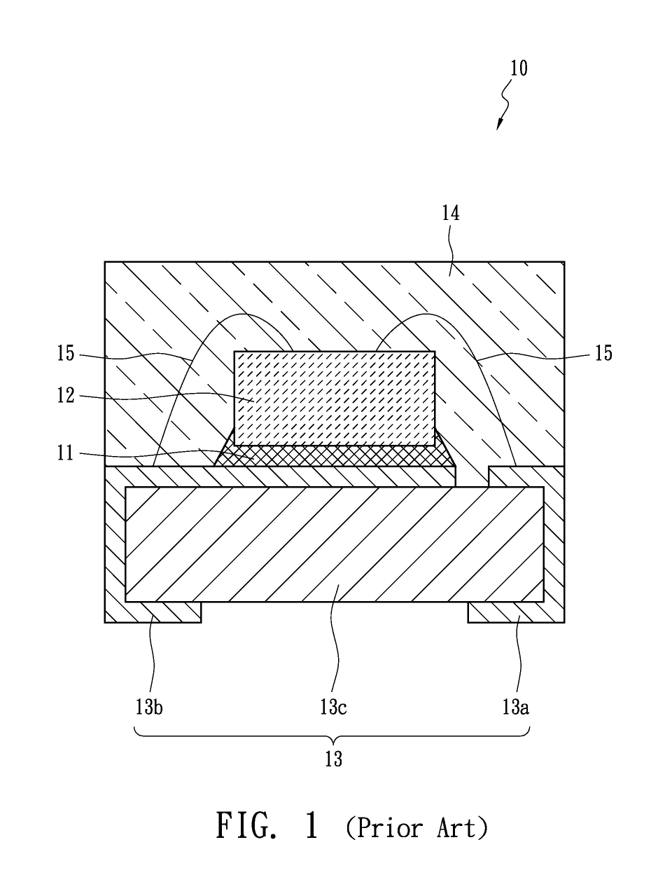

### DETAILED DESCRIPTION OF THE INVENTION

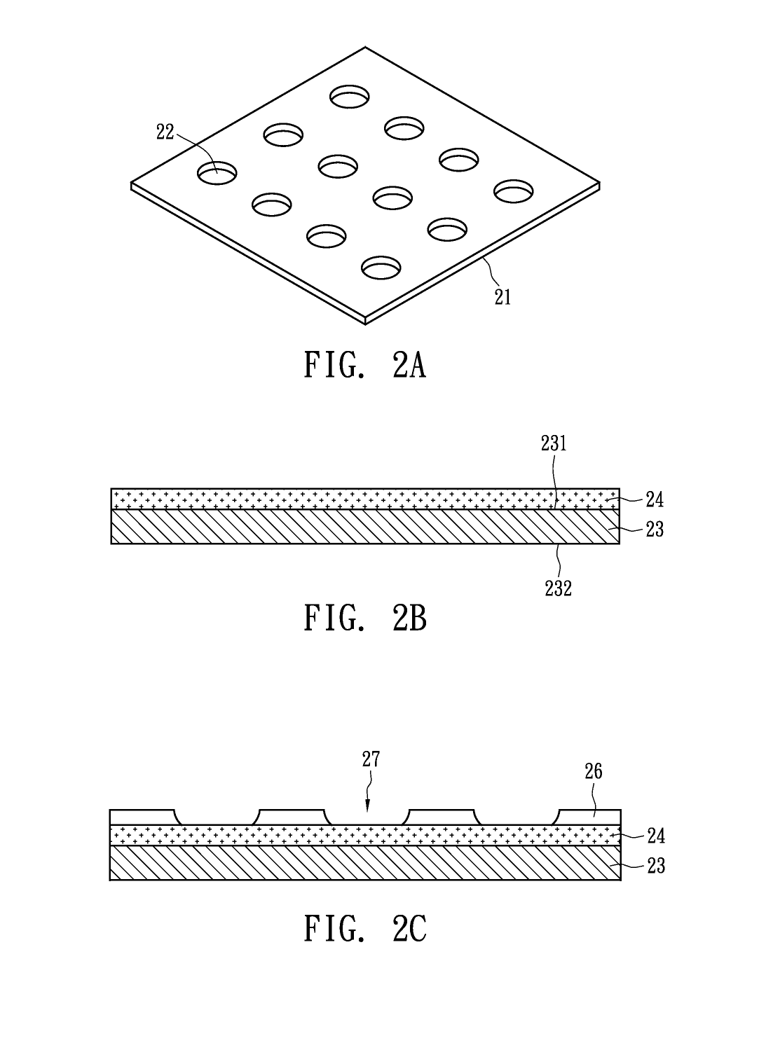

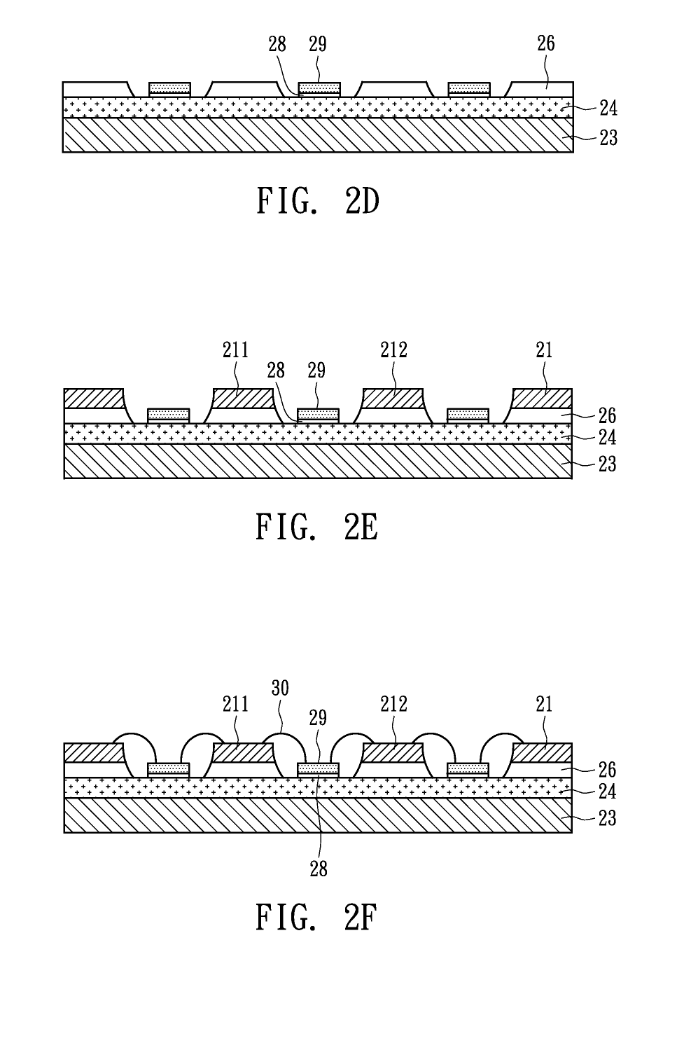

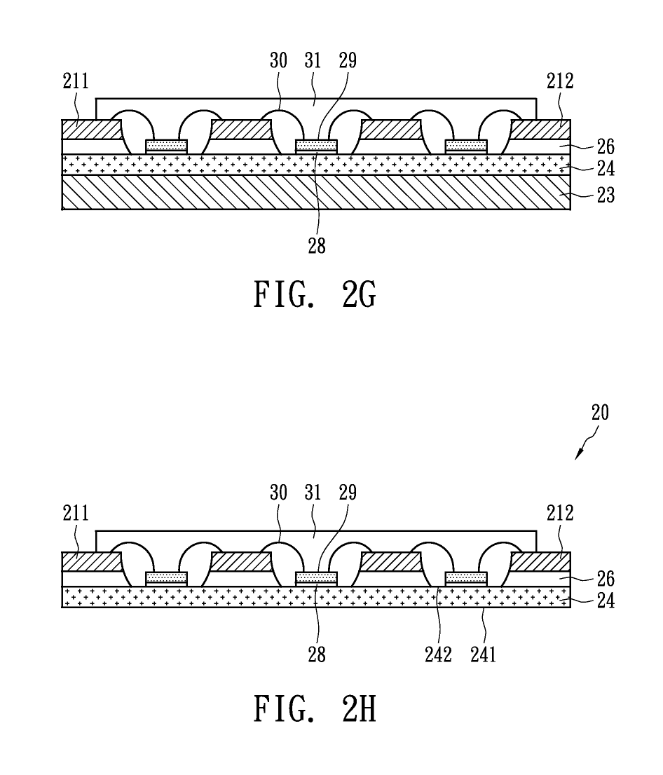

FIGS. 2A through 2H are schematic illustrations showing the manufacturing steps of the package module structure of compound semiconductor devices in accordance with a first embodiment of the present invention. FIG. 2A shows a circuit board 21 with holes 22. In an embodiment, the circuit board 21 is a flexible printed circuit (FPC), e.g., FR-4, and is prepared in advance as a component for sequentially fabricating the package module structure of compound semiconductor devices.

In FIG. 2B, a temporary substrate 23 includes a first surface 231 and a second surface 232. In this drawing, the first surface 231 is an upper surface and the second surface 232 is a lower surface. The temporary substrate 23 may be made of a metallic material, a ceramic material or a polymer material. A heat dissipation film 24 is formed on the first surface 231 of the temporary substrate 23. The heat dissipation film 24 may be a metallic film without a circuit pattern and may be made of silver, nickel, copper, tin, aluminum or an alloy of the aforesaid metallic materials. Furthermore, conductive transparent materials such as indium tin oxide (ITO), indium zinc oxide (IZO), indium gallium oxide (IGO) and indium tungsten oxide (IWO) also are suitable for the material of heat dissipation film 24.

In FIG. 2C, dielectric layers 26 are formed on the heat dissipation film 24 by molding or injection, and an opening 27 is formed between every two dielectric layers 26. The openings 27 are structures of reflective cups, and their positions correspond to those of the holes 22 of the circuit board 21.

In FIG. 2D, compound semiconductor dies 29 are mounted on the heat dissipation film 24 in the openings 27 through a die bonding paste 28, and then the circuit board 21 is put on dielectric layers 26. The holes 22 of the circuit board 21 correspond to the openings 27, as shown in FIG. 2E. In this embodiment, the circuit board 21 at the two sides of the opening 27 is provided with an N-type electrode 211 and a P-type electrode 212. In an embodiment, the dies 29 may be LEDs, laser diodes, photo sensors, or photocells.

In FIG. 2F, through wire-bonding technologies, metal wires 30 are used for electrically connecting the dies 29, the N-type electrode 211 and the P-type electrode 212.

In FIG. 2G, a transparent encapsulation material 31 such as epoxy resin and silicone is overlaid on the dies 29, the N-type electrode 211, the P-type electrode 212, and the metal wires 30. The transparent encapsulation material 31 is further mixed with fluorescent powders so that a secondary light can be emitted from the excited fluorescent powders. The secondary light is mixed with a primary light emitted from the dies 29 to form a white light or electromagnetic radiation waves with multiple wavelengths. The material of the mixed fluorescent powders may be YAG, TAG, silicate, or nitride-based fluorescent powders. The transparent encapsulation material 31 may be formed by transfer-molding or injection molding.

After the transparent encapsulation material 31 is hardened, the temporary substrate 23 is removed by bending, separating, etching, laser cutting or grinding. Therefore, a first surface 241 of the heat dissipation film 24 is exposed, and accordingly the package module structure 20 of the compound semiconductor device is completed as shown in FIG. 2H. The first surface 241 of the heat dissipation film 24 is opposite to a second surface 242, and the second surface 242 is still covered by the transparent encapsulation material 31.

Because the N-type electrode 211 and the P-type electrode 212 at two ends of the package module structure 20 are not covered by the transparent encapsulation material 31, they can serve as outer contacts for surface mounting. Furthermore, the heat generated from the dies 29 is directly transferred by the heat dissipation film 24 with a superior conductive coefficient so that the heat dissipation efficiency of the package module structure 20 is significantly improved. Compared with prior arts, the thickness of the package module structure 20 can be reduced to 0.3-1.0 mm, and the package module structure 20 can be viewed as a super-thin structure.

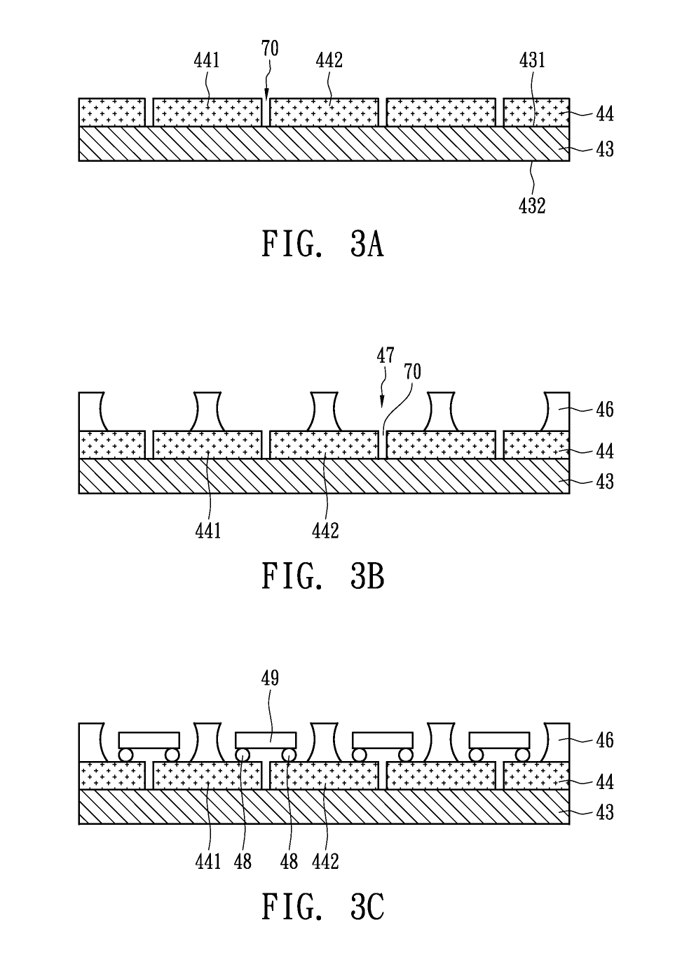

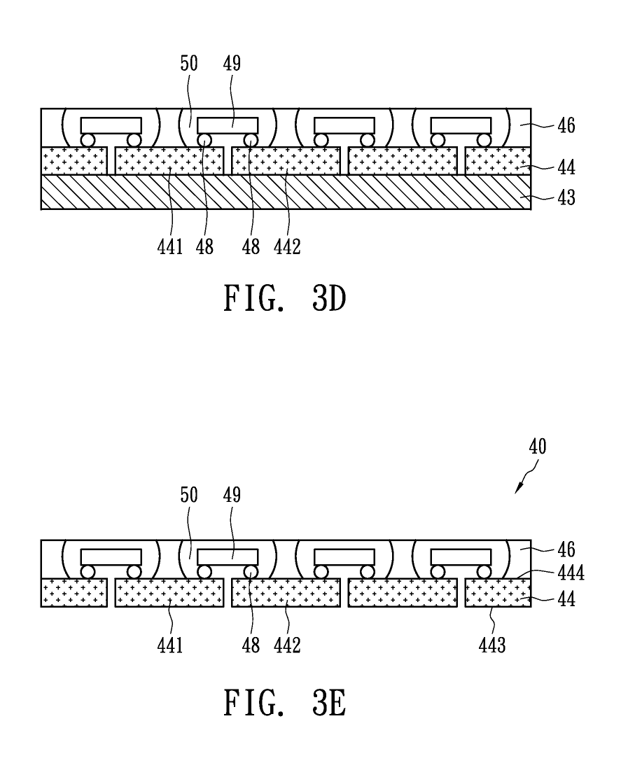

FIGS. 3A through 3E are schematic illustrations showing the manufacturing steps of the package module structure of compound semiconductor devices in accordance with a second embodiment of the present invention, in which flip chip technology is employed.

In FIG. 3A, a temporary substrate 43 includes a first surface 431 and a second surface 432. In this drawing, the first surface 431 is an upper surface and the second surface 432 is a lower surface. The temporary substrate 43 may be made of a metallic material, a ceramic material or a polymer material. A heat dissipation film 44 with a pattern is formed on the first surface 431 through printing, screening, electroform, chemical plating (or electroless plating) or sputtering. In this embodiment, the heat dissipation film 44 is an electrically conductive film including an N-type electrode 441 and a P-type electrode 442, which are disposed at two sides of each isolation gap 70 to form required circuits of the package module structure. The electrically conductive film may be made of silver, nickel, copper, tin, aluminum or an alloy of the aforesaid metallic materials. Furthermore, conductive transparent materials such as indium tin oxide (ITO), indium zinc oxide (IZO), indium gallium oxide (IGO) and indium tungsten oxide (IWO) also are suitable for the material of the heat dissipation film 44.

In FIG. 3B, dielectric layers 46 are formed on the heat dissipation film 44 by molding or injection, and an opening 47 is formed between every two dielectric layers 46. The openings 47 correspond to the isolation gaps 70 of the heat dissipation film 44.

In FIG. 3C, the dies 49 are mounted on the heat dissipation film 44 through flip chip bonding, in which plural bumps 48 electrically connect the dies 49, the N-type electrode 441, and the P-type electrode 442.

In FIG. 3D, a transparent encapsulation material 50 such as epoxy resin and silicone is formed in the openings 47, by which the transparent encapsulation material 50 is overlaid on the dies 49, the N-type electrode 441, and the P-type electrode 442. The transparent encapsulation material 50 may be overlaid on the dies 49 by transfer-molding or injection molding.

After the transparent encapsulation material 50 is hardened, the temporary substrate 43 is removed by bending, separating, etching, laser cutting or grinding, so that a first surface 443 of the heat dissipation film 44 is exposed. Accordingly, the package module structure 40 of the compound semiconductor device is completed, as shown in FIG. 3E. The first surface 443 of the heat dissipation film 44 is opposite to a second surface 444, and the second surface 444 is still covered by the transparent encapsulation material 50.

Because the N-type electrode 441 and the P-type electrode 442 of the package module structure 40 of the compound semiconductor device are not covered by the transparent encapsulation material 50, they can serve as outer contacts for surface mounting. Furthermore, the heat generated from the dies 49 is directly transferred by the heat dissipation film 44 with a superior conductive coefficient so that the heat dissipation efficiency of the package module structure 40 is improved.

The process sequence is not restricted for the above embodiments, but should comply with the module process from a high temperature to a low temperature.

The flip chip technology is employed for the second embodiment, and in comparison with the first embodiment, the thickness of the package module structure 40 generally can be further decreased to 0.1-0.6 mm. The package module structures 20 and 40 can be light bars or light plates as desired, thereby providing various applications.

In comparison with prior arts, in addition to being applied to thin structures, the entire lower surface of the package module structures 20 and 40 is a heat dissipation film that can effectively dissipate heat generated by the compound semiconductor devices, so as to increase heat dissipation efficiency. Accordingly, brightness, thermal stability and lifetime of the compound semiconductor devices can be increased. Further, the use of FPC provides flexibility, and can be applied for the backend module with a bending surface.

The above-described embodiments of the present invention are intended to be illustrative only. Those skilled in the art may devise numerous alternative embodiments without departing from the scope of the following claims.

What is claimed is:

1. A package module structure of compound semiconductor devices, comprising:
a heat dissipation film;
a dielectric layer including a plurality of openings formed on the heat dissipating film;
a plurality of compound semiconductor dies formed on the heat dissipation film in the openings of the dielectric layer, with adjacent two compound semiconductor dies being separated by the dielectric layer;
means for mounting the plurality of compound semiconductor dies on the heat dissipation film; and
a transparent encapsulation material overlaying the plurality of compound semiconductor dies.

2. The package module structure of claim 1, wherein the heat dissipation film is made of silver, nickel, copper, tin, aluminum or an alloy thereof or indium tin oxide, indium zinc oxide, indium gallium oxide or indium tungsten oxide.

3. The package module structure of claim 1, further comprising a circuit board that has a first electrode and a second electrode disposed on the dielectric layer at two sides of the compound semiconductor die.

4. The package module structure of claim 3, wherein the circuit board is a flexible printed circuit.

5. The package module structure of claim 4, wherein the package module structure has a thickness between 0.3 and 1.0 mm.

6. The package module structure of claim 1, wherein the dielectric layer at two sides of the opening forms a reflective cup.

7. A method for fabricating a package module structure of compound semiconductor devices, comprising the steps of:
providing a heat dissipation film;
forming a dielectric layer on the heat dissipation film, the dielectric layer comprising a plurality of openings;
mounting a plurality of compound semiconductor dies on the heat dissipation film in the openings;
forming a circuit board on the dielectric layer, the circuit board comprising a first electrode and a second electrode disposed on the dielectric layer at two sides of the compound semiconductor die;
electrically connecting the plurality of compound semiconductor dies to the first electrode and the second electrode; and
overlaying a transparent encapsulation material on the compound semiconductor dies.

8. The method of claim 7, wherein the heat dissipation film is formed on a temporary substrate, and then the temporary substrate is removed after the semiconductor dies are overlaid with the transparent encapsulation material.

9. The method of claim 8, wherein the temporary substrate is removed by bending, separating, etching, laser cutting or grinding.

10. The method of claim 8, wherein the temporary substrate is made of a metallic material, a ceramic material or a polymer material.

11. The method of claim 7, wherein the heat dissipation film is made of silver, nickel, copper, tin, aluminum or the alloy thereof.

12. The method of claim 7, wherein the plurality of compound semiconductor dies, the first electrode and the second electrode are electrically connected by wire bonding using metal wires.

13. A method for fabricating a package module structure of compound semiconductor devices, comprising the steps of:
providing a heat dissipation film having a first electrode and a second electrode;
forming a dielectric layer on the heat dissipation film, the dielectric layer comprising a plurality of openings;
mounting a plurality of compound semiconductor dies on the heat dissipation film in the openings and electrically connecting the compound semiconductor dies to the first electrode and the second electrode; and
overlaying a transparent encapsulation material on the compound semiconductor dies.

14. The method of claim 13, wherein the heat dissipation film is formed on a temporary substrate, and then the temporary substrate is removed after the semiconductor dies are overlaid with the transparent encapsulation material.

15. The method of claim 14, wherein the heat dissipation film is a electrically conductive film and is formed on the temporary substrate by printing, screening, electroform, chemical plating or sputtering, and the temporary substrate is removed by bending, separating, etching, laser cutting or grinding.

16. The method of claim 15, wherein the electrically conductive film is made of silver, nickel, copper, tin, aluminum or the alloy thereof.

17. The method of claim 14, wherein the temporary substrate is made of a metallic material, a ceramic material or a polymer material.

18. The method of claim 13, wherein the step of mounting a plurality of compound semiconductor dies on the heat dissipation film in the openings is performed by flip chip bonding and electrically connecting the compound semiconductor dies to the first electrode and the second electrode through a plurality of bumps.

19. The method of claim 13, wherein the compound semiconductor dies are light emitting diodes, laser diodes or photo sensors.

20. The method of claim 13, wherein the transparent encapsulation material is epoxy resin or silicone.
